(19) United States
(12) Patent Application Publication
(10) Pub. No.: US 2018/0130545 A1
(43) Pub. Date: May 10, 2018

(54) System For Deciding Memory Test Coverage Based On Test Granularity And Method Thereof

(71) Applicants: Inventec (Pudong) Technology Corporation, Shanghai (CN); Inventec Corporation, Taipei City (TW)

(72) Inventor: Yan Li, Shanghai (CN)

(21) Appl. No.: 15/622,835

(22) Filed: Jun. 14, 2017

(30) Foreign Application Priority Data
Nov. 8, 2016 (CN) 201610981529.5

(51) Int. Cl. G11C 29/36; G11C 29/38

(52) U.S. Cl. CPC G11C 29/36; G11C 29/38

(57) ABSTRACT

The present disclosure illustrates a system for deciding a memory test coverage based on a test granularity and a method thereof. In the system, a dynamic random access memory (DRAM) address sequence is generated based on a test granularity, the memory address sequence is transformed to a physical address, and all or part of the memory is tested based on the physical address. As a result, the system and the method of the present disclosure may control test coverage, and may achieve the effect of improving efficiency of memory test.

### CROSS-REFERENCE TO RELATED APPLICATION

This application claims the benefit of Chinese Patent Application No. 201610981529.5, filed Nov. 8, 2016.

### BACKGROUND OF THE INVENTION

### 1. Field of the Invention

The present disclosure relates to a memory test system and a method thereof, more particularly to a system for deciding memory test coverage based on a test granularity, and a method thereof.

### 2. Description of the Related Art

In a memory test of a system integration test, it is difficult to reach balance between test efficiency and test coverage. In recent years, the server system has memory load of TB level, so the test efficiency may become very low when the need of the test coverage must be satisfied. However, the low test efficiency is unacceptable when there are a large number of online shipments of servers.

In order to increase the test efficiency, the test coverage must be reduced. Most conventional test solutions merely provide a user to select a percentage of all loaded memories to be tested. However, the conventional test solution performs the test on the memory randomly allocated by an operating system, but lacks scientifically reasonable specificity. As a result, the conventional test solution is unable to guarantee the test coverage, and the test coverage becomes a very ambiguous and random indicator, which causes potential security risk for the system.

Therefore, what is need is to develop a system for detecting the memory test coverage to solve the conventional technology problem that the conventional test solution using randomly-allocated memory is unable to guarantee the test coverage.

### SUMMARY OF THE INVENTION

In order to solve the problem that the conventional test solution using randomly-allocated memory is unable to guarantee the test coverage, the present disclosure is to provide a system for deciding memory test coverage based on a test granularity, and a method thereof.

According to an embodiment, the present disclosure provides a system for deciding a memory test coverage based on a test granularity. The system is applicable to a computer which is installed with at least one dual in-line memory module (DIMM), and includes an input module, a sequence generating module, an address transform module, and a test module. The input module is configured to provide selection for a test granularity. The sequence generating module is configured to generate at least one dynamic random access memory (DRAM) address sequence based on the test granularity. The address transform module is configured to transform each of the at least one DRAM address sequence to one physical address corresponding thereto. The test module is configured to perform a test on the at least one DIMM based on each physical address.

According to an embodiment, the present disclosure further provides a method for deciding a memory test coverage based on a test granularity. The method is applicable to a computer which is installed with at least one DIMM, and the method includes following steps: selecting a test granularity; generating at least one DRAM address sequence based on the test granularity; transforming each of the at least one DRAM address sequence to one physical address corresponding thereto; and performing a test on the at least one DIMM based on each physical address.

According to above content, the difference between the present disclosure and the conventional technology is that the system and method of the present disclosure may generate the DRAM address sequences based on the test granularity, and transform the generated DRAM address sequence to the physical addresses corresponding thereto, and perform the test based on the generated physical addresses. By above technical means, the conventional technology problem may be solved, and the technical effect of improving efficiency of memory test may be achieved.

### BRIEF DESCRIPTION OF THE DRAWINGS

The structure, operating principle and effects of the present disclosure will be described in detail by way of various embodiments which are illustrated in the accompanying drawings.

FIG. 1 is a framework diagram of a system for deciding a memory test coverage based on a test granularity, in accordance with the present disclosure.

FIG. 2 is a flowchart showing the steps in an operation of a method for deciding a memory test coverage based on a test granularity, in accordance with the present disclosure.

### DETAILED DESCRIPTION OF THE PREFERRED EMBODIMENTS

The following embodiments of the present invention are herein described in detail with reference to the accompanying drawings. These drawings show specific examples of the embodiments of the present invention. It is to be understood that these embodiments are exemplary implementations and are not to be construed as limiting the scope of the present invention in any way. Further modifications to the disclosed embodiments, as well as other embodiments, are also included within the scope of the appended claims. These embodiments are provided so that this disclosure is thorough and complete, and fully conveys the inventive concept to those skilled in the art. Regarding the drawings, the relative proportions and ratios of elements in the drawings may be exaggerated or diminished in size for the sake of clarity and convenience. Such arbitrary proportions are only illustrative and not limiting in any way. The same reference numbers are used in the drawings and description to refer to the same or like parts.

It is to be understood that, although the terms ‘first’, ‘second’, ‘third’, and so on, may be used herein to describe various elements, these elements should not be limited by these terms. These terms are used only for the purpose of distinguishing one component from another component. Thus, a first element discussed herein could be termed a second element without altering the description of the present invention. As used herein, the term “or” includes any and all combinations of one or more of the associated listed items.

In the present disclosure, a DRAM address sequence may be generated based on the test granularity, and after the DRAM address sequence is transformed to the physical address corresponding thereto, a DIMM may be tested for different test coverage based on the generated physical address.

The test granularity of the present disclosure may include all DIMMs, all ranks, all banks, one row or one column, so that the user may select to test all DIMMs only, or test all ranks only, or test all banks only, or test all rows only, or test all columns.

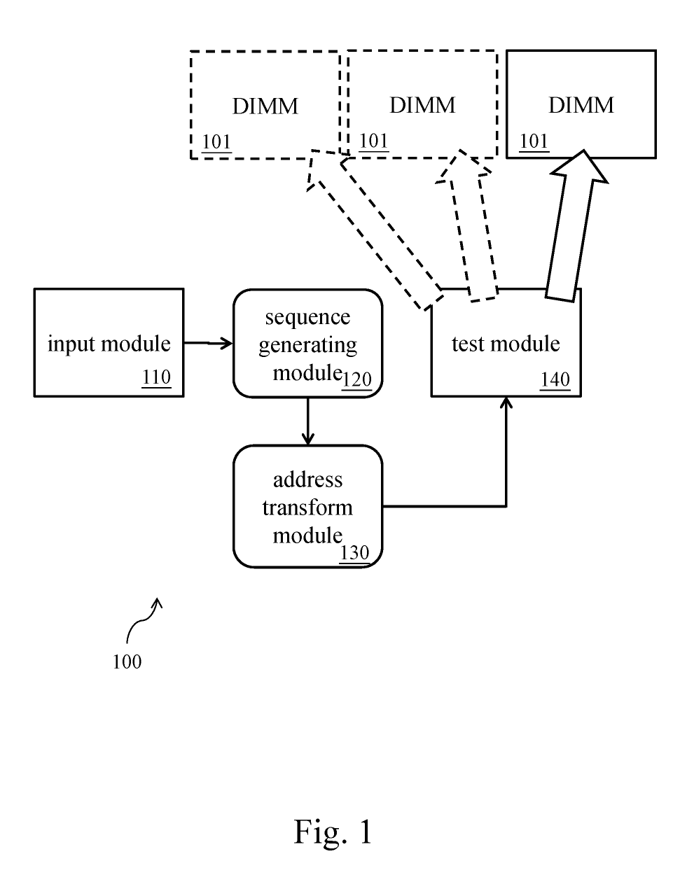

The following refers to FIG. 1, which is a framework diagram of a system for deciding a memory test coverage based on a test granularity, to illustrate an operation of the system of the present disclosure. As shown in FIG. 1, the system of the present disclosure includes an input module 110, a sequence generating module 120, an address transform module 130 and a test module 140.

The input module 110 is configured to provide a user to select a test granularity, that is, the user may use the input module 110 to select different coverage test for DIMMs, ranks, banks, rows, or columns.

The sequence generating module 120 is configured to generate one or more DRAM address sequence corresponding to the selected test granularity provided by the input module 110. The dynamic random access memory (DRAM) address sequence generated by the sequence generating module 120 may include a socket identification (ID), a memory controller (MC) ID, a channel ID, a DIMM ID, a rank ID, a bank ID, a row ID, and a column ID.

When the test granularity is selected as the DIMM, the sequence generating module 120 may directly ignore the rank ID, the bank ID, the row ID and the column ID, that is, fields of the rank ID, the bank ID, the row ID and the column ID of the DRAM address sequence are filled with “0”; the sequence generating module 120 may generate the DRAM address sequence according to the numbers of memory slot, memory controller, channel and DIMM in the computer 100. For example, suppose that the numbers of the memory slot, the memory controller, the channel of the computer 100 are two respectively and the number of the DIMM of the computer 100 is one, the sequence generating module 120 may generate eight DRAM address sequences “00000000”, “00100000”, “01000000”, “01100000”, “10000000”, “10100000”, “11000000” and “11100000”.

Similarly, when the test granularity is selected as the rank, the sequence generating module 120 may directly ignore the bank ID, the row ID and the column ID, and may generate the DRAM address sequence according to the numbers of the memory slot, the memory controller, the channel, the DIMM and the rank of the computer 100. When the test granularity is selected as the bank, the sequence generating module 120 may directly ignore the row ID and the column ID, and may generate the DRAM address sequence according to the numbers of the memory slot, the memory controller, the channel, the DIMM, the rank and the bank. When the test granularity is selected as the row, the sequence generating module 120 may directly ignore the column ID, and generate the DRAM address sequence according to the numbers of the memory slot, the memory controller, the channel, the DIMM, the rank, the bank and the row.

When the test granularity is selected as the column, it indicates to test all bits in the memories, the sequence generating module 120 may generate the DRAM address sequence according to the numbers of the memory slot, the memory controller, the channel, the DIMM, the rank, the bank, the row and the column of the computer 100 without ignoring any data field. The sequence generating module 120 may test all DIMMs by using a manner the same as that of conventional memory test manner for completely testing all memories.

The address transform module 130 is configured to transform the DRAM address sequence generated by the sequence generating module 120 to a physical address corresponding thereto.

Generally, according to the socket ID, the memory controller ID, the channel ID, the DIMM ID, the rank ID contained in the DRAM address sequence, the address transform module 130 may determine the physical address of each of the DIMMs 101 installed in the computer 100. In some embodiments, the address transform module 130 may determine a rank address first according to the socket ID, the memory controller ID, the channel ID, the DIMM ID and the rank ID, and then determine the channel address according to the rank address, the channel ID, the DIMM ID and the rank ID, and then determine the physical address according to the channel address, the socket ID, the memory controller ID and the channel ID. However, the manner that the address transform module 130 transforms the Dram address sequence to the physical address is not limited to aforementioned example.

The test module 140 is configured to test the DIMM 101 installed in the computer 100 based on the physical address generated by the address transform module 130. Based on the physical address generated by the address transform module 130, the test module 140 may allocate memory for a storage space provided by the DIMM 101 first, and then test the allocated memory.

In some embodiments, the test module 140 may execute various test algorithms on each physical address by a communication cycle respectively, that is, each test algorithm may be performed on each physical addresses by a communication cycle.

In some embodiments, the test module 140 may generate a test report after the test is completed, and conditions of each DIMM 101 of each memory slot may be described clearly in the test report, for example, an error occurs in a test process for some DRAM addresses of some DIMMs of some memory slots.

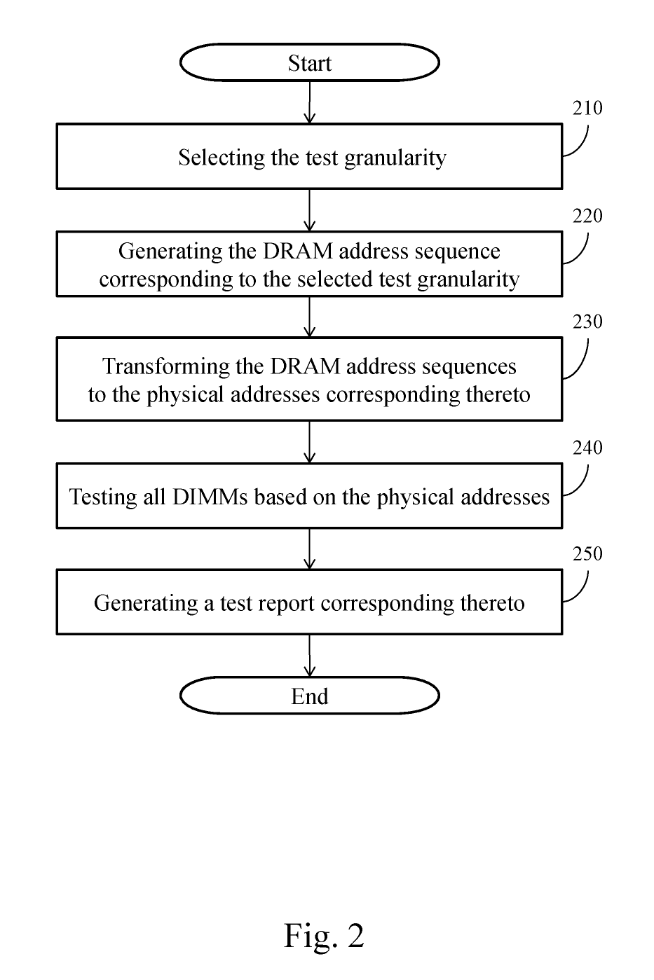

The following refer to an embodiment to explain operations of the system and method of the present disclosure in reference with FIG. 2, which is a flowchart showing the steps in an operation of the method for deciding the memory test coverage based on the test granularity, in accordance with the present disclosure. In this embodiment, suppose that the computer 100 is a notebook computer using an x86_64 architecture, but the present disclosure is not limited thereto.

First of all, in a step 210, the input module 110 may provide a user to select the test granularity.

In a step 220, the sequence generating module 120 generates the DRAM address sequence corresponding to the selected test granularity provided by the input module 110. In this embodiment, suppose that the selected test granularity is the rank level and the numbers of the memory slot, the memory controller, the channel, the DIMM and the rank are two respectively, the sequence generating module 120 may generate thirty-two DRAM address sequences including “00000000”, “00010000”, “00100000”, “00110000”, “01000000”, “01010000”, “01100000”, “01110000”, . . . , “11101000” and “11111000”.

In a step 230, after the sequence generating module 120 generates the DRAM address sequences corresponding to the selected test granularity in the step 220, the address transform module 130 may transform the DRAM address sequences, generated by the sequence generating module 120, to the physical addresses corresponding thereto respectively. In this embodiment, suppose that the address transform module 130 respectively transforms the thirty-two DRAM address sequences generated by the sequence generating module 120 to thirty-two 46-bit physical addresses.

In a step 240, after the address transform module 130 transforms the DRAM address sequences to the physical addresses corresponding thereto in the step 230, the test module 140 tests all DIMMs 101 installed in the computer 100 based on the physical addresses transformed from the DRAM address sequences. In this embodiment, there are thirty-two physical addresses, so the test module 140 may perform tests on each DIMM 101 by at least thirty-two times, and in each test, at least one test algorithm is performed on a specific rank, which is represented by a physical address, by a communication cycle. As a result, after the test module 140 completes the thirty-two tests on the physical addresses, ranks of all DIMMs 101 installed in the computer 100 are tested by at least one time, thereby guaranteeing the test coverage effectively.

Furthermore, in a step 250, the test module 140 may also generate a test report after the test module completes the test on all DIMMs 101 installed in the computer 100.

To summarize, the difference between the present disclosure and the conventional technology is that the system and method of the present disclosure may generate the DRAM address sequences based on the test granularity, and transform the generated DRAM address sequence to the physical addresses corresponding thereto, and perform test on all or a part of the storage spaces of the DIMMs based on the generated physical addresses. By above technical means, the problem that the conventional test manner using randomly allocated memory is unable to guarantee the test coverage may be solved, and the technical effect of improving efficiency of memory test may be achieved.

Furthermore, the system for deciding the memory test coverage based on the test granularity and a method thereof of the present disclosure may be implemented by hardware, software or a combination thereof, and the implementation of the system and the method may be centralized in a computer system or be distributed in different devices of multiple interconnected computer systems.

The present disclosure disclosed herein has been described by means of specific embodiments. However, numerous modifications, variations and enhancements can be made thereto by those skilled in the art without departing from the spirit and scope of the invention set forth in the claims.

What is claimed is:

1. A method for deciding a memory test coverage based on a test granularity, applicable to a computer which is installed with at least one dual in-line memory module (DIMM), and the method comprising:
selecting a test granularity;
generating at least one dynamic random access memory (DRAM) address sequence based on the test granularity;
transforming each of the at least one DRAM address sequence to one physical address corresponding thereto; and
performing a test on the at least one DIMM based on each physical address.

2. The method according to claim 1, wherein the step of transforming each of the at least one DRAM address sequence to one physical address corresponding thereto further comprises:
determining a range of each of the physical address based on a socket identification (ID), a memory controller ID, a channel ID, a DIMM ID, a rank ID contained in the corresponding DRAM address sequence.

3. The method according to claim 1, wherein the step of selecting the test granularity comprises:
selecting all DIMMs, all ranks, all banks, one row, or one column to test.

4. The method according to claim 1, wherein the step of performing the test on the at least one DIMM based on each physical address further comprises:
performing at least one test algorithm to test each physical address by a communication cycle.

5. The method according to claim 1, after the step of performing the test on the least one DIMM based on each physical address, the method further comprising: generating a test report corresponding to the test.

6. A system for deciding a memory test coverage based on a test granularity, applicable to a computer which is installed with at least one DIMM, and the system comprising:
an input module configured to provide selection for a test granularity;
a sequence generating module configured to generate at least one DRAM address sequence based on the test granularity;
an address transform module configured to transform each of the at least one DRAM address sequence to one physical address corresponding thereto; and
a test module configured to perform a test on the at least one DIMM based on each physical address.

7. The system according to claim 6, wherein the address transform module determines a range of each of the physical address based on a socket ID, a memory controller ID, a channel ID, a DIMM ID, a rank ID contained in the at least one DRAM address sequence.

8. The system according to claim 6, wherein the input module provides to select all DIMMs, all ranks, all banks, one row, or one column for test.

9. The system according to claim 6, wherein the test module performs at least one test algorithm to test each physical address by a communication cycle.

10. The system according to claim 6, wherein the test module further generates a test report corresponding to the test.
